(19) United States
(12) Patent Application Publication
(10) Pub. No.: US 2007/0170571 A1
(43) Pub. Date: Jul. 26, 2007

(54) Low profile semiconductor system having a partial-cavity substrate

(76) Inventors: Mark A. Gerber, Lucas, TX (US); Kurt P. Wachtler, Richardson, TX (US); Abram M. Castro, Fort Worth, TX (US)

Correspondence Address: TEXAS INSTRUMENTS INCORPORATED, P O BOX 655474, M/S 3999, DALLAS, TX, 75265, US

(21) Appl. No.: 11/376,394

(22) Filed: Mar. 15, 2006

Related U.S. Application Data
(60) Provisional application No. 60/762,550, filed on Jan. 26, 2006.

(51) Int. Cl. H01L 23/02; H01L 21/00

(52) U.S. Cl. 257/686; 438/109; 257/E23.085; 257/700

(57) ABSTRACT

A system (100), which has an electrically insulating substrate (101) with a thickness, a first and a second surface. Electrically conductive paths (110) extend through the insulating body from the first to the second surface and have exit ports (120) at the end of the conductive paths on the first and the second surface. A cavity (130) extends downwardly from the first surface to a depth less than the thickness; the bottom of the cavity and the first substrate surface have contact pads (141). The substrate further has electrically conductive lines (150) between the first and the second surface and under the cavity, contacting the paths. The system includes a stack of semiconductor chips (160,170) with bond pads; one chip is attached to the bottom of the cavity and one chip is electrically connected to substrate contact pads.

### FIELD OF THE INVENTION

The present invention is related in general to the field of semiconductor devices and processes, and more specifically to structure and processes of low profile packages for vertically integrated semiconductor systems.

### DESCRIPTION OF THE RELATED ART

The long-term trend in semiconductor technology to double the functional complexity of its products every 18 months (Moore's “law”) has several implicit consequences. First, the higher product complexity should largely be achieved by shrinking the feature sizes of the chip components while holding the package dimensions constant; preferably, even the packages should shrink. Second, the increased functional complexity should be paralleled by an equivalent increase in reliability of the product. Third, the cost per functional unit should drop with each generation of complexity so that the cost of the product with its doubled functionality would increase only slightly.

As for the challenges in semiconductor packaging, the major trends are efforts to shrink the package outline so that the package consumes less area and less height when it is mounted onto the circuit board, and to reach these goals with minimum cost (both material and manufacturing cost). Recently, another requirement was added to this list, namely the need to design packages so that stacking of chips and/or packages becomes an option to increase functional density and reduce device thickness. Furthermore, it is hoped that a successful strategy for stacking chips and packages would shorten the time-to-market of innovative products, which utilize available chips of various capabilities (such as processors and memory chips) and would not have to wait for a redesign of chips.

Recent applications especially for hand-held wireless equipments, combined with ambitious requirements for data volume and high processing speed, place new, stringent constraints on the size and volume of semiconductor components used for these applications. Consequently, the market place is renewing a push to shrink semiconductor devices both in two and in three dimensions, and this miniaturization effort includes packaging strategies for semiconductor devices as well as electronic systems.

### SUMMARY OF THE INVENTION

Applicants recognize the need for a fresh concept of achieving a coherent, low-cost method of assembling high lead count, yet low contour devices; the concept includes substrates and packaging methods for stacking devices. The goal should be vertically integrated semiconductor systems, which may include integrated circuit chips of functional diversity. The resulting system should have excellent electrical performance, mechanical stability, and high product reliability. Further, it will be a technical advantage that the fabrication method of the system is flexible enough to be applied for different semiconductor product families and a wide spectrum of design and process variations.

One embodiment of the present invention is a semiconductor system, which has an electrically insulating substrate with a first and a second surface. Electrically conductive paths extend through the insulating body from the first to the second surface and have exit ports at the end of the conductive paths on the first and the second surface. A cavity extends downwardly from the first surface deep enough to accommodate a stack of semiconductor chips; the bottom of the cavity and the first substrate surface have contact pads. The substrate further has electrically conductive lines between the first and the second surface and under the cavity, contacting the paths. The system includes a stack of semiconductor chips with bond pads; one chip is attached to the bottom of the cavity and one chip is electrically connected to substrate contact pads. The system may further include metal reflow bodies attached to the substrate exit ports. In addition, the system may include encapsulation material, which protects the chip stack and the electrical connections.

In one embodiment of the invention the electrical connections of the top chip connect to substrate contact pads located on the first substrate surface. In another embodiment, the electrical connections of the top chip connect to substrate contact pads located on the bottom of the cavity.

Another embodiment of the invention is a substrate for use in assembling semiconductor systems. The substrate has an electrically insulating body with a first and a second surface, a plurality of electrically conductive paths extending through the insulating body from the first to the second surface, with exit ports on the first and the second surfaces suitable for attaching metal reflow bodies. The first substrate surface has a cavity deep enough to accommodate a stack of semiconductor chips; the bottom of the cavity and the first substrate surface have contact pads. The substrate further has a plurality of electrically conductive lines between the first and the second surface, contacting the paths, selected lines extending through the substrate under the cavity.

Another embodiment of the invention is a method for fabricating a packaged semiconductor system. In a strip of an electrically insulating sheet-like body with a first and a second surface is a plurality of electrically conductive paths formed, which extend through the insulating body from the first to the second surface and have exit ports on the first and the second surface suitable for attaching metal reflow bodies. Further, a plurality of electrically conductive lines between the first and the second surface is formed, contacting the paths; selected lines extend through the length of the strip.

An array of cavities is formed, which are recessed from the first strip surface; the cavities are deep enough to accommodate a stack of semiconductor chips. On the bottom of the cavities and on the first body surface are contact pads.

A stack of at least two vertically arranged semiconductor chips is assembled in each cavity so that the bottom chip is attached to the bottom of the cavity and one of the chips is electrically connected to the contact pads. The chip stack and the electrical connections may be protected by encapsulation compound. The method may further include the step of attaching metal reflow bodies to the exit ports.

Finally, individual units are singulated from the strip so that each unit represents a semiconductor system including an assembled chip stack in a cavity of the insulating substrate with conductive lines, paths, and ports.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 illustrates a schematic cross section of an embodiment of a packaged semiconductor system using a substrate with a partial cavity to accommodate a stack of vertically integrated chips.

FIG. 2 depicts a schematic cross section of another embodiment of a packaged semiconductor system using a substrate with a partial cavity to accommodate a stack of vertically integrated chips.

FIG. 3 illustrates a schematic cross section of another embodiment of a packaged semiconductor system using a substrate with a partial cavity to accommodate a stack of vertically integrated chips.

### DETAILED DESCRIPTION OF THE PREFERRED EMBODIMENTS

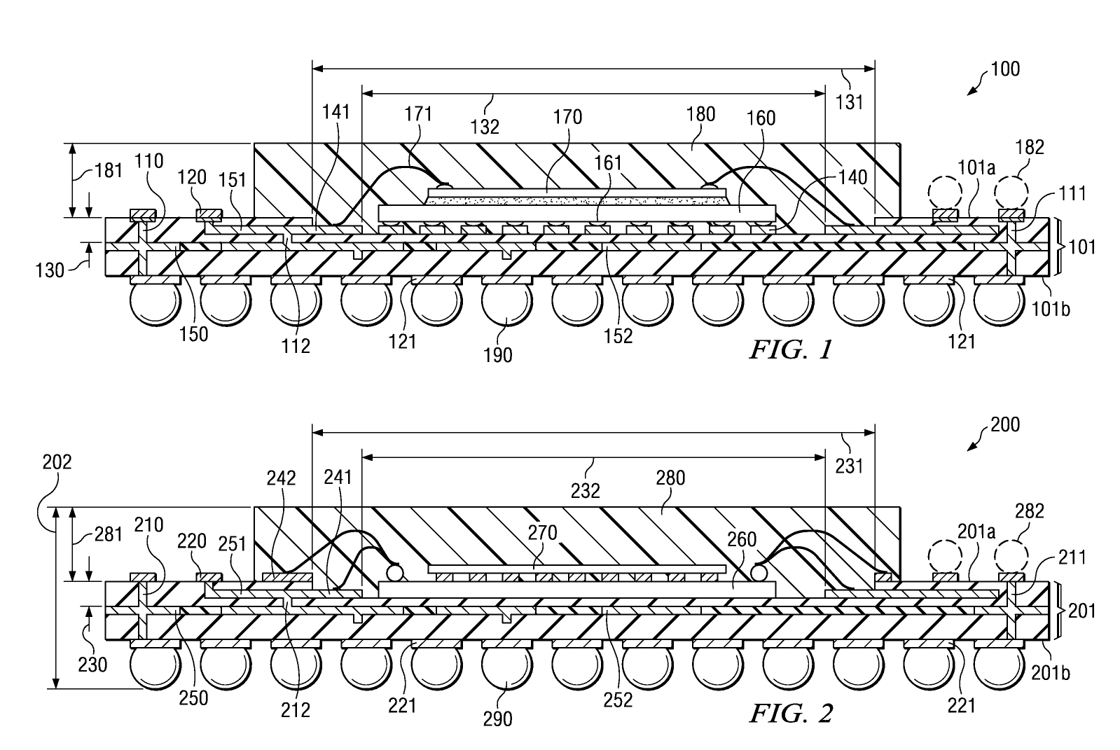

FIG. 1 is an example of an embodiment of the present invention, illustrating a vertically integrated semiconductor system packaged in an encapsulation compound and, by means of solder bodies, prepared for connection to external parts. Due to a partial cavity in the substrate for facilitating the system integration, the system has a low profile.

In FIG. 1, the system generally designated 100 has a substrate 101 made of an insulating body with a thickness, a first surface 101a and second surface 101b. Preferred materials for substrate 101 are ceramics or polymers in a sheet-like configuration; the polymers may be stiff or compliant. The substrates have a thickness in the range from about 50 to 500 μm.

FIG. 1 shows portions of the substrate so that electrically conductive paths 110, 111, 112, etc. are displayed, which extend through the insulating body from the first surface 101a to the second surface 101b. The paths are preferably made of copper or a copper alloy. The paths may have input/output terminals (often referred to as exit ports) 120, 121, etc., on the first surface 101a and on the second surface 101b. Exit ports are typically made of copper or copper alloy and preferably have a surface suitable for attaching metal reflow bodies such as tin or tin alloy solder balls. Commonly, the ports surfaces include gold layer, or a stack of nickel and palladium layers. The distance between ports can be designed according to the needs for interconnection. Selected exit ports may be spaced apart by less than 125 μm center to center.

FIG. 1 indicates that substrate 101 has a cavity, which begins at first surface 101a and reaches to a depth 130. This depth is less than the thickness of the substrate and is thus referred to as a partial cavity. The cavity has side walls, for many embodiments four side walls; in other products, for which the substrate is provided in strip form of a certain width, the cavity may extend across the width and thus have only two side walls.

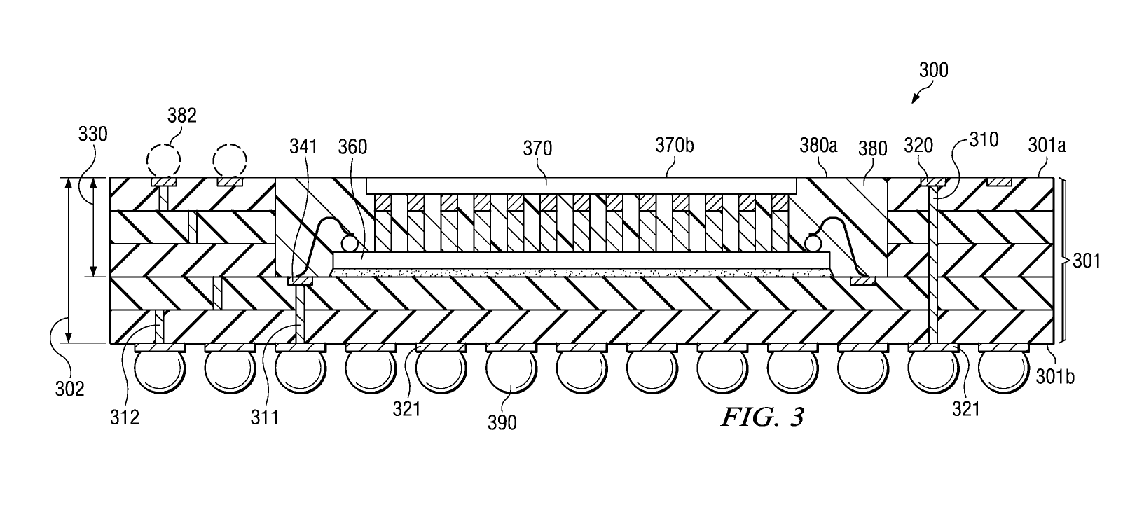

In the example of FIG. 1, the cavity cascades in steps from the surface 101a to a step of width 131 and further to a minimum width 132 (in the example of FIG. 3, the cavity is shown to have a uniform width). The size of the minimum width 132 is determined by the width of the semiconductor chip, which will be assembled in the cavity. An analogous statement can be made for the length of the cavity, which is not shown in FIG. 1.

On the bottom of the cavity are contact pads; they are preferably made of copper or a copper alloy with a surface suitable for (gold) wire bonding and attachment to gold studs. A preferred surface is a gold layer or a stack of a nickel layer followed by a palladium layer. In FIG. 1, an example of contact pad is designated 140, another example 141. Both pads may be patterned from an electrically conductive metal layer (preferably copper) embedded in substrate 101. In the example of FIG. 1, pad 141 is actually the last step of the partial cavity. The distance between contact pads can be designed according to the needs for interconnection. Selected contact pads may be spaced apart by less than 100 μm center to center.

In some embodiments, there may be additional contact pads on the first substrate surface 101 surrounding the partial cavity. As illustrated in FIG. 2, an example pad is designated 242. These pads are also preferably made of copper with a surface suitable for wire bonding.

Referring to FIG. 1, substrate 101 further has a plurality of electrically conductive lines 150, 151, etc., located between the first surface 101a and the second surface 101b of the substrate. The lines are patterned from sheets preferably made of copper or a copper alloy. The lines may be in contact with certain paths. Selected lines may extend through the length and width of the substrate under the cavity; FIG. 1 indicates portions 152 of such lines.

The partial cavity provides space for assembling a stack of semiconductor chips on a substrate without unduly increasing the thickness of the device. FIG. 1 shows an example of two chips 160 and 170 arranged vertically into a stack. The chips are shown as having unequal size and unequal thickness, but other chips may, of course, be of equal size and thickness. Both chips have bond pads suitable for wire bonding or flip-chip ball bonding. The stack is formed by using an adhesive, such as an epoxy- based or polyimide-based attach material, to attach the passive sides of chip 160 and chip 170 together.

The stack is assembled on the substrate so that the bottom chip 160 is attached to the bottom of the substrate cavity and the top chip 170 is electrically connected to substrate contact pads 141 using wire bonding 171. Contact pads 141 are preferably located on the bottom of the partial cavity in FIG. 1; an alternative structure, wherein the contact pads are located on the first substrate surface, is illustrated in FIG. 2. The attachment of bottom chip 160 is enabled by flip-chip contacts 161, preferably gold studs.

In order to complete system 100, encapsulation 180 is protecting the chip stack and the electrical connections. Preferably, encapsulation 180 uses an epoxy-based molding compound, which also fills the gaps between the studs 161 and thus contributes to absorption of thermo-mechanical stresses. The height 181 of the encapsulation material over the substrate surface 101a, and thus the overall thickness of system 100, can be reduced by increasing the depth 130 of the partial cavity and utilizing the depth to lower as much of the chip stack height as possible into the cavity. It further helps to keep the wire span of bonding wires 171 low. Height 181 should preferably be not much taller than the height needed for attaching interconnecting members 182 onto the exit ports 120. Members 182 are tin- or tin-alloy-based solder elements from an external part, such as another packaged semiconductor device. System 100 thus lends itself to create package-on-package products of tightly controlled overall thickness.

FIG. 1 further indicates that system 100 has metal reflow bodies 190 attached to substrate exit ports 121; these bodies are preferably tin or tin-alloy solder balls and enable the connection of system 100 to external parts (such as circuit boards).

Another embodiment of the invention is depicted in FIG. 2, illustrating a vertically integrated semiconductor system 200 of a stack of semiconductor chips 260 and 270 assembled on a substrate 201 with a partial cavity 230 and packaged in an encapsulation compound 280. Due to the partial cavity in the substrate for facilitating the system integration, the system has a low profile 202.

Similar to the example in FIG. 1, substrate 201 is made of an insulating body with a thickness, a first surface 201a and second surface 201b. Preferred materials for substrate 201 are ceramics or polymers in a sheet-like configuration; the polymers may be stiff or compliant. The substrates have a thickness in the range from about 50 to 500 μm.

FIG. 2 shows portions of the substrate so that electrically conductive paths 210, 211, 212, etc. are displayed, which extend through the insulating body from the first surface 201a to the second surface 201b. The paths are preferably made of copper or a copper alloy. The paths may have exit ports 220, 221, etc., on the first surface 201a and on the second surface 201b. Exit ports are typically made of copper or copper alloy and preferably have a surface (for instance, gold or palladium) suitable for attaching metal reflow bodies such as tin or tin alloy solder balls.

Contact pads 242 on surface 201a are formed from the same metalization level as exit ports 220 and surround the periphery of the cavity. Preferably, contact pads 242 have a surface, such as gold, suitable for wire bonding.

FIG. 2 indicates that substrate 201 has a cavity, which begins at first surface 201a and reaches to a depth 230. This depth is less than the thickness of the substrate and is thus referred to as a partial cavity. In the example of FIG. 2, the cavity cascades in steps from the surface 201a to a step of width 231 and further to a minimum width 232. The size of the minimum width 232 is determined by the width of the semiconductor chip, which will be assembled in the cavity (an analogous statement can be made for the length of the cavity, which is not shown in FIG. 2).

On the bottom of the partial cavity is a metal portion 241 exposed which serves as a contact pad for wire bonds from the chip bond pads and is formed from a conductive line embedded in substrate 201. Contact pad 241 is typically made of copper or a copper alloy and has preferably a surface of gold layer.

Substrate 201 further has electrically conductive lines 250, 251, etc., disposed between the first surface 201a and the second surface 201b of the substrate. The lines are patterned from sheets preferably made of copper or a copper alloy. The lines may be in contact with certain paths. Some lines may extend through the length and width of the substrate under the cavity; FIG. 2 indicates portions 252 of such lines.

The partial cavity provides space for assembling a stack of semiconductor chips. FIG. 2 shows an example of two chips 260 and 270 arranged vertically into a stack. While in this example the chips are shown as having unequal size and unequal thickness, other chips may be of equal size and thickness. The bottom chip has bond pads suitable for wire bonding. The stack is formed by flipping the top chip and stud-assembling it on contact studs of the bottom chip.

The stack is assembled on the substrate so that the bottom chip 260 is attached to the bottom of the substrate cavity and electrically connected to substrate contact pads 241 in the cavity and/or contact pads 242 on the substrate surface using wire bonding.

In order to complete system 200, encapsulation 280 is protecting the chip stack and the electrical connections. Preferably, encapsulation 280 uses an epoxy-based molding compound, which also fills the gaps between the metal studs connecting the chips; the molding compound thus contributes to the absorption of thermo-mechanical stresses. The height 281 of the encapsulation material over the substrate surface 201a, and thus the overall thickness 202 of system 200, can be reduced by increasing the depth 230 of the partial cavity and utilizing the depth to lower as much of the chip stack height as possible into the cavity. For further system thickness control, it helps to keep the span of the bonding wires low. Height 281 should preferably be not much taller than the height needed for attaching interconnecting members 282 onto the exit ports 220. Members 282 are tin- or tin-alloy-based solder elements from an external part, such as another packaged semiconductor device. System 200 thus lends itself to create package-on-package products of tightly controlled overall thickness.

FIG. 2 further indicates that system 200 has metal reflow bodies 290 attached to substrate exit ports 221; these bodies are preferably tin or tin-alloy solder balls and enable the connection of system 200 to external parts (such as circuit boards).

Another embodiment of the invention is illustrated in FIG. 3, depicting a vertically integrated semiconductor system 300 of a stack of semiconductor chips 360 and 370 assembled on a substrate 301 with a partial cavity 330 and packaged in an encapsulation compound 380. Due to the partial cavity in the substrate for facilitating the system integration, the system has a low profile 302. Substrate 301 is made of an insulating body (ceramics, polymers), preferably supplied in an elongated strip in the thickness range from about 50 to 500 μm with first surface 301a and second surface 301b.

FIG. 3 shows portions of the substrate so that electrically conductive paths 310, 311, 312, etc. (preferably copper) are displayed, which extend from the first surface 301a to the second surface 301b. At the ends of the conductive paths are exit ports 320, 321, etc. (preferably copper with a solderable and bondable surface), on the first surface and second surface, respectively. In FIG. 3, partial cavity 330 extends downwardly from the first surface 301a to a depth less than the thickness of the substrate; the full depth 330 is reached in one step.

Substrate 301 further has electrically conductive lines 350, 351, etc. (preferably copper), disposed between the first surface 301a and the second surface 301b of the substrate. The lines may be in contact with certain paths. Some lines may extend through the length and width of the substrate under the cavity.

The partial cavity provides space for assembling a stack of semiconductor chips with bond pads. FIG. 3 shows an example of two chips 360 and 370 arranged vertically into a stack. While in this example the chips are shown as having unequal size and unequal thickness, other chips may be of equal size and thickness. The stack is formed by flipping the top chip and stud-assembling it on contact studs of the bottom chip.

The stack is assembled on the substrate so that one chip is attached to the bottom of the cavity, and one chip is electrically connected to substrate contact pads 341 using wire bonding. In FIG. 3, contact pads 341 are disposed on the bottom of the cavity to provide a system surface planar with the first substrate surface 301a; alternatively, the contact pads may also be located on the first substrate surface.

In order to complete system 300, encapsulation 380 is protecting the chip stack and the electrical connections. Preferably, encapsulation 380 uses an epoxy-based molding compound, which also fills the gaps between the metal studs connecting the chips; the molding compound thus contributes to the absorption of thermo-mechanical stresses. In FIG. 3, the surface 380a of encapsulation 380 is coplanar with first surface 301a of the substrate and passive surface 370b of chip 370. The overall thickness 302 of system 300 can thus be kept thin, including the thickness of the substrate and the height of metal reflow bodies 390 (preferably tin-based solder balls).

FIG. 3 shows interconnecting members 382 onto the exit ports 320. Members 282 are preferably tin- or tin-alloy-based solder elements from an external part, such as another packaged semiconductor device. System 300 thus lends itself to create package-on-package products of tightly controlled overall thickness.

Another embodiment of the invention is a method for fabricating a packaged semiconductor system, especially a vertically integrated system. The method is based on providing a substrate, which has a partial cavity formed in it. The fabrication process of creating the substrate includes the steps of:

providing a strip of an electrically insulating elongated sheet-like body (ceramic, polymer, etc.) with a thickness, a first and a second surface;

forming a plurality of electrically conductive paths extending from the first surface to the second surface.

The preferred method is creating via holes and filling them with copper;

forming exit ports at the end of the conductive paths on the first and the second surface. Preferably, the exit ports are made of a layer of copper or copper alloy with a metallurgical surface (layer of gold, palladium, etc.) amenable to wire bonding and solder attachment;

forming a plurality of electrically conductive lines between the first and the second surface, contacting the paths, whereby selected lines extend through the length of the strip. Preferably, the lines are made of patterned copper layers, some of them disposed under the cavities; and

forming cavities extending downwardly from the first surface, the cavities having contact pads on the bottom. The preferred method of creating the cavities is by cutting or stamping. The depth of the cavities is less than the thickness of the substrate.

After the substrate has been manufactured, semiconductor chips with bond pads are provided. Stacks composed of at least two vertically aligned chips are formed; in this forming process, the chips may be joined by flipping to bring metal studs into contact, or by attaching with and adhesive.

A chip stack is then assembled in each cavity so that the bottom chip is attached to the bottom of the cavity and one of the chips is electrically connected to the contact pads. The contact pads may be disposed on the bottom of the cavity, or they may be located on the surface of the substrate.

Preferably, the cavities, including the chip stack and the electrical connections, are filled with an encapsulation compound. A preferred compound is an epoxy-based molding compound, and the preferred encapsulation method is the transfer molding technology; it is a well-controlled and low cost batch process.

Metal reflow bodies such as tin-based solder balls are attached to the exit ports. Finally, the substrate strip is singulated (for instance, by sawing) into individual packaged systems.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the process step of encapsulating can be omitted when the integration of the system has been achieved by flip-chip assembly.

It is therefore intended that the appended claims encompass any such modifications or embodiment.

1. A system comprising:
a substrate having an insulating body with a thickness,
a first and a second surface;
conductive paths extending from the first surface to the second surface;
exit ports at the end of the conductive paths on the first and the second surface;
a cavity extending downwardly from the first surface to a depth less than the thickness;
contact pads disposed in the cavity and on the first surface;
conductive lines disposed between the first and the second surface and under the cavity, contacting the paths; and
a stack of semiconductor chips having bond pads, one chip of the stack attached to the bottom of the cavity, and one chip electrically connected to substrate contact pads.

2. The system according to claim 1 further including metal reflow bodies attached to the substrate exit ports.

3. The system according to claim 1 further including encapsulation material protecting the chip stack and the electrical connections.

4. The system according to claim 1 wherein the electrical connections of the chip connect to substrate contact pads located on the first substrate surface.

5. The system according to claim 1 wherein the electrical connections of the chip connect to substrate contact pads located on the bottom of the cavity.

6. A system for use in assembling semiconductor devices, comprising:
an electrically insulating body with a thickness, a first and a second surface;
conductive paths extending from the first surface to the second surface;
exit ports at the end of the conductive paths on the first and the second surface;
a cavity extending downwardly from the first surface to a depth less than the thickness;
contact pads disposed in the cavity and on the first surface; and
conductive lines disposed between the first and the second surface and under the cavity, contacting the paths.

7. A method for fabricating a packaged semiconductor system, comprising the steps of:
providing a substrate fabricated by the steps of:
providing a strip of an electrically insulating sheet-like body with a thickness, a first and a second surface;
forming a plurality of electrically conductive paths extending from the first surface to the second surface;
forming exit ports at the end of the conductive paths on the first and the second surface;
forming a plurality of electrically conductive lines between the first and the second surface, contacting the paths, whereby selected lines extend through the length of the strip; and
forming cavities extending downwardly from the first surface to a depth less than the thickness, the cavities having contact pads on the bottom;
providing semiconductor chips having bond pads;
forming stacks composed of at least two vertically aligned chips;
assembling a chip stack in each cavity so that the bottom chip is attached to the bottom of the cavity and one of the chips is electrically connected to the contact pads;
filling the cavities including the chip stack and the electrical connections with encapsulation compound;
attaching metal reflow bodies to the exit ports; and
singulating the strip into individual packaged systems.
